(19) United States
(12) Patent Application Publication
(10) Pub. No.: US 2003/0053893 A1
(43) Pub. Date: Mar. 20, 2003

(54) Substrate processing apparatus and a method for fabricating a semiconductor device by using same

(75) Inventors: Tatsuhisa Matsunaga, Tokyo (JP); Hiroshi Sekiyama, Tokyo (JP); Kouichi Noto, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Tokyo (JP)

(21) Appl. No.: 10/230,181

(22) Filed: Aug. 29, 2002

(30) Foreign Application Priority Data
Aug. 31, 2001 (JP) 2001-264317

(51) Int. Cl. H01L 21/205

(52) U.S. Cl. 414/217; 414/939; 432/239; 118/719

(57) ABSTRACT

A substrate processing apparatus includes at least two processing units provided around a substrate transfer chamber including a substrate transfer device for transferring substrates, wherein said at least two processing units include at least one batch processing unit, an M number of product substrates being processed simultaneously in one batch process with M being set to be less than or equal to the number of product substrates carried by a product substrate carrier, and all the product substrates contained in a product substrate carried by the product substrate carrier being processed in one batch process of said at least one batch processing unit. A method for fabricating a semiconductor device includes the step of sequentially processing plural product substrates in at least two processing units arranged around a substrate transfer chamber.

### FIELD OF THE INVENTION

The present invention relates to a substrate processing apparatus and method used in fabricating a semiconductor device; and, more particularly, to a substrate processing apparatus and method capable of sequentially forming various kinds of thin films, such as an oxide layer, a nitride layer, or a metallic layer, on a substrate, e.g., a semiconductor wafer (hereinafter referred to as a wafer), on which integrated circuits including therein semiconductor devices are fabricated, wherein the surface of the substrate is maintained in a highly clean condition during the film forming process.

### BACKGROUND OF THE INVENTION

Japanese Patent Application Laid-Open Publication No. 1995-101675 discloses a vertical diffusion and CVD apparatus for fabricating semiconductor devices by forming, e.g., a silicon oxide layer, a silicon nitride layer, or a metallic layer on a wafer while preventing a formation of a natural oxide film thereon. The vertical diffusion and CVD apparatus includes a hermetically sealed cassette chamber capable of receiving a cassette (wafer carrier) having a plurality of wafers accommodated therein; a loadlock chamber (wafer transfer chamber) having a wafer transfer device for transferring the wafers between the cassette disposed in the cassette chamber and a boat; and a reaction chamber (process tube), the boat being transferred between the loadlock chamber and the reaction chamber. The cassette chamber and the loadlock chamber are in communication with the loadlock chamber and the reaction chamber through gate valves, respectively. A nitrogen atmosphere is maintained in the loadlock chamber, which is not evacuated into vacuum.

However, the vertical diffusion and CVD apparatus suffers from a drawback of a low throughput. That is, since the film formed wafers are transferred to a subsequent processing equipment after being returned to the cassette, the throughput of the aforementioned apparatus is deteriorated by the time required in returning the wafers to the cassette, unloading the cassette from the apparatus and transferring cassette to the subsequent equipment. Further, a cassette is usually made of a resin or the like. For this reason, the processed wafers need be cooled down to room temperature and thus the throughput of the aforementioned apparatus is further deteriorated by the time required in cooling down to a temperature acceptable for wafer transferring (for example, 5 to 60° C.) from a temperature (e.g., 600° C.) of the wafers immediately after being unloaded from the reaction chamber.

Japanese Patent No. 2759368 describes a vertical type heat treatment apparatus capable of sequentially performing various processes on a substrate. The vertical type heat treatment apparatus includes a process tube for forming CVD films on a plurality of wafers loaded in a boat; a first loadlock chamber installed under the process tube to airtightly surround a vertical moving region of the boat; a second loadlock chamber airtightly connected to the first loadlock chamber; a third loadlock chamber installed between the second loadlock chamber and the atmosphere and having a stocker for receiving plural wafers; a transfer arm installed in the second loadlock chamber and for transferring the wafers between the boat and the stocker; and a natural oxide film removing device, airtightly combined with the second loadlock chamber, for processing the wafers one by one to remove a natural oxide film on the each wafer before forming a CVD film thereon. Further, in the vertical type heat treatment apparatus, the wafers loaded in the stocker are transferred one by one to the natural oxide film removing device by the transfer arm. After removing the natural oxide film on a wafer provided from the stocker, the wafer is returned from the natural oxide film removing device to the stocker by the transfer arm. Thereafter, the natural oxide film removed wafer returned to the stocker is batch-processed in the process tube after being transferred from the stocker to the first loadlock chamber by the transfer arm.

In the above-mentioned vertical heat treatment apparatus, the processes, i.e., unloading wafers from the wafer stocker accommodating therein plural wafers, processing wafer, and returning the processed wafers to the same wafer stocker are carried out on a single wafer basis. Therefore, there occur waiting periods during the processes, lowering the throughput of the apparatus.

### SUMMARY OF THE INVENTION

It is, therefore, an object of the present invention to provide a substrate processing apparatus and method for fabricating semiconductor devices, which is capable of performing sequential processes in a highly clean surface condition while preventing a deterioration of throughput or an increase in cost.

In accordance with one aspect of the invention, there is provided a substrate processing apparatus including: at least two processing units provided around a substrate transfer chamber which includes a substrate transfer device for transferring substrates; wherein said at least two processing units include at least one batch processing unit, M number of product substrates being processed simultaneously in one batch process, with M being set to be less than or equal to the maximum number of product substrates to be contained in a product substrate carrier, and all the product substrates contained in the product substrate carrier being processed in one batch process carried out in said at least one batch processing unit.

In accordance with another aspect of the invention, there is provided a substrate processing apparatus including: at least one batch processing unit, provided around a substrate transfer chamber including a substrate transfer device for transferring substrates, for processing N number of product substrates simultaneously in one batch process; a single substrate processing unit provided around the substrate transfer chamber for processing one or P number of product substrates at a time, P being smaller than N; and a stocker provided around the substrate transfer chamber for temporarily storing said one or P number of product substrates processed by the single substrate processing unit.

In accordance with still another aspect of the invention, there is provided a method for fabricating a semiconductor device, including the steps of: processing one or more product substrates in a first processing unit arranged around a substrate transfer chamber, transferring the product substrates from the first processing unit to a second processing unit arranged around the substrate transfer chamber; processing the product substrates in the second processing unit, wherein said two processing units include at least one batch processing unit, M number of product substrates being processed simultaneously in one batch process by said at least one batch processing unit with M being set to be less than or equal to the maximum number of product substrates which to be contained in a product substrate carrier, and all the product substrates contained in the product substrate carrier being processed in one batch process carried out in said at least one batch processing unit.

In accordance with still another aspect of the invention, there is provided a method for fabricating a semiconductor device, comprising the steps of: processing at least one substrate in one processing unit; introducing an inert or a neutral gas into the processing unit after the processing step, to increase a pressure level therein to be higher than that during a process of transferring substrates; lowering the pressure level of said processing unit down to the pressure level during the process of transferring substrates; and transferring the substrates processed in said processing unit.

### BRIEF DESCRIPTION OF THE DRAWINGS

The above and other objects and features of the present invention will become apparent from the following description of preferred embodiments given in conjunction with the accompanying drawings, in which:

FIG. 1 shows a horizontal cross sectional view of a multi-chamber type CVD apparatus in accordance with a first preferred embodiment of the present invention;

FIG. 2 describes a side cross sectional view of the multi-chamber type CVD apparatus of FIG. 1;

FIG. 3 illustrates a rear cross sectional view of a first CVD unit of the multi-chamber type CVD apparatus of FIG. 1;

FIG. 4 offers a rear cross sectional view of the first CVD unit during the film forming process; and

FIG. 5 provides a horizontal cross sectional view of a multi-chamber type CVD apparatus in accordance with a second preferred embodiment of the present invention.

### DETAILED DESCRIPTION OF THE PREFERRED EMBODIMENTS

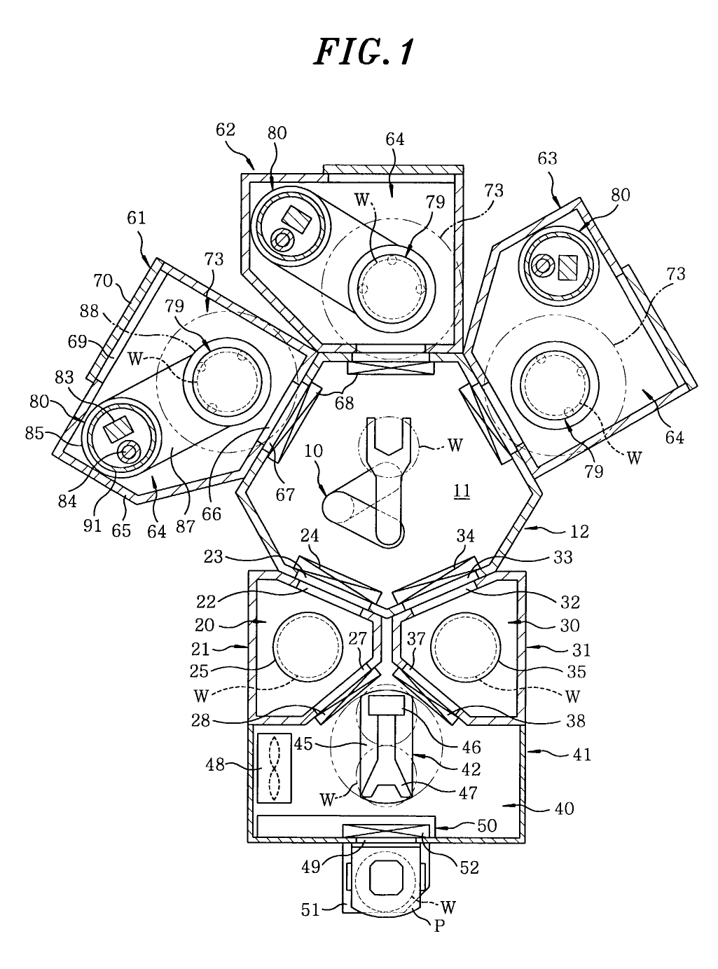

Hereinafter, a first preferred embodiment of the present invention will now be described with reference to the accompanying drawings of FIGS. 1 to 4.

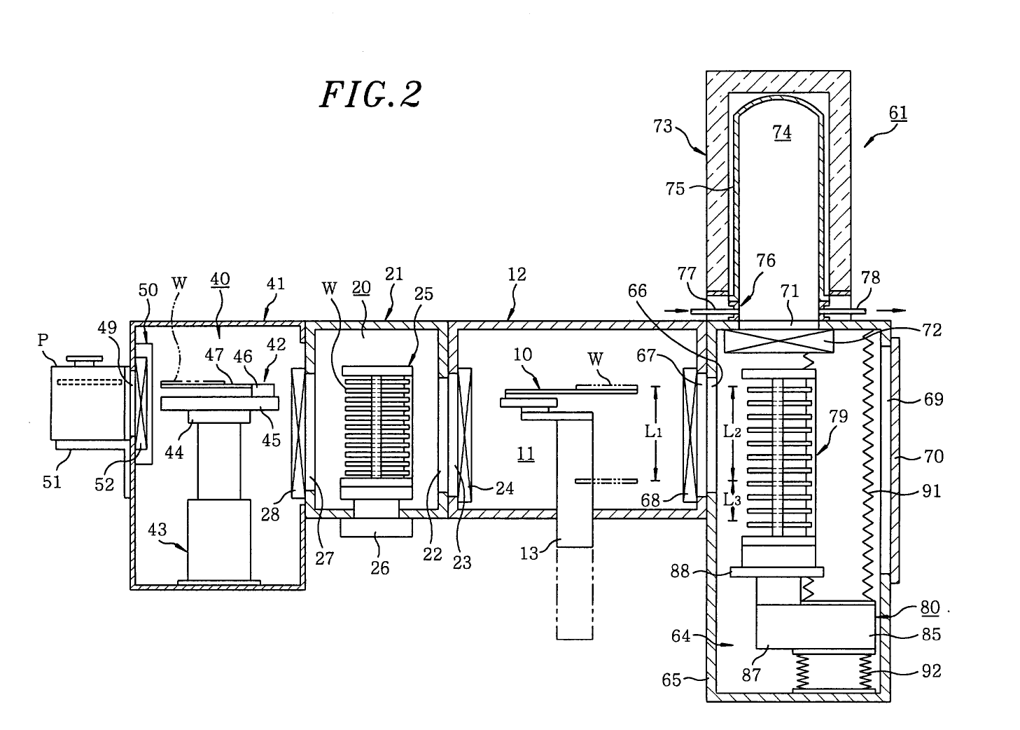

As shown in FIGS. 1 and 2, a substrate processing apparatus in accordance with the first preferred embodiment of the present invention, is a multi-chamber type CVD apparatus (hereinafter referred to as a CVD apparatus), which is used to form an insulating layer, e.g., composed of a silicon oxide or a silicon nitride and/or a metallic layer, e.g., composed of Ta₂O₅ or Ru on a wafer in the course of manufacturing semiconductor integrated circuit (hereinafter referred to as IC).

Further, in the CVD apparatus in accordance with the first preferred embodiment, a FOUP (front opening unified pod, hereinafter referred to as a pod) is used as a wafer carrier. Throughout the specification, a front, a rear, a left and a right side of the apparatus are defined with reference to FIG. 1. That is, the front side refers where a pod opener 50 is located; the rear side refers to a side opposite to the front side, i.e., where a second CVD unit 62 is located; the left side refers where a loading chamber 20 is located; and the right side refers where a unloading chamber 30 is located.

As shown in FIGS. 1 and 2, the CVD apparatus is provided with a negative pressure wafer transfer chamber 11 having a wafer transfer device 10 at a center portion thereof for transferring wafers W under a pressure lower than the atmospheric pressure (hereinafter referred to as a negative pressure). A housing 12 of the negative pressure wafer transfer chamber 11 has a heptagonal prism shape with two top and bottom ends closed and is of a loadlock chamber structure capable of maintaining therein negative pressure under an airtight condition. The wafer transfer device 10 is formed of a scara (selective compliance assembly robot arm) type robot and is configured to be hermetically raised or lowered by an elevator 13 installed at a lower wall of the housing 12 of the negative pressure wafer transfer chamber 11. As shown in FIG. 2, an elevating stroke L₁ of the wafer transfer device 10 is smaller than a wafer charging range L₂ of a boat 79 which will be described later, and a shortage length L₃ can be accommodated by an elevator 80 of the boat 79. Thus, the size of the elevator 13 of the wafer transfer device 10 can be reduced by that much.

Adjacently connected to the two front side walls of the housing 12 of the negative pressure wafer transfer chamber 11 are the loading chamber 20 and the unloading chamber 30, respectively. Each of a housing 21 of the loading chamber 20 and a housing 31 of the unloading chamber 30 has a hexagonal prism shape with two closed top and bottom ends and is of a loadlock chamber structure capable of enduring negative pressure therein. Loading openings 22 and 23 are installed at adjoining side walls of the housing 21 of the loading chamber 20 and the housing 12 of the negative pressure wafer transfer chamber 11, respectively, and installed at the loading opening 23 of the negative pressure wafer transfer chamber 11 is a gate valve 24 for opening or closing the loading openings 22 and 23. Similarly, unloading openings 32 and 33 are installed at adjoining side walls of the housing 31 of the unloading chamber 30 and the housing 12 of the negative pressure wafer transfer chamber 11, respectively, and installed at the unloading opening 33 of the negative pressure wafer transfer chamber 11 is a gate valve 34 for opening or closing the unloading openings 32 and 33.

Installed inside the loading chamber 20 is a temporary storage 25, and installed inside the unloading chamber 30 is a temporary storage 35. The temporary storages 25 and 35 have identical structures to that of the boat 79 and are configured such that a plurality of wafers W are horizontally maintained by maintenance grooves. As shown in FIG. 2, the temporary storage 25 is configured to rotate in a horizontal plane by a rotary actuator 26. Though not shown, the temporary storage 35 has a configuration identical to that of the temporary storage 25.

Disposed in front of the loading chamber 20 and the unloading chamber 30 is a positive pressure wafer transfer chamber 40 having a wafer transfer device 42 for transferring the wafers W under a pressure higher than the atmospheric pressure (hereinafter referred to as a positive pressure). A housing 41 of the positive pressure wafer transfer chamber 40 has an airtight structure capable of maintaining positive pressure therein. The wafer transfer device 42 has an elevator 43 for vertically raising or lowering a rotary actuator 44, which is configured to rotate a linear actuator 45 installed at top surface thereof in a horizontal plane. Installed at the top surface of the linear actuator 45 is a moving stage 46, which is configured to be horizontally moved by the linear actuator 45. Horizontally mounted on the moving stage 46 are tweezers 47 for supporting the wafers W thereunder.

As shown in FIG. 1, a clean air supplying unit 48 is installed in the positive pressure wafer transfer chamber 40 to supply clean air thereinto. Installed at a side wall of the housing 21 of the loading chamber 20 adjoining the positive pressure wafer transfer chamber 40 is a loading opening 27 for connecting the positive pressure wafer transfer chamber 40 to the loading chamber 20, and installed at a side of the loading opening 27 toward the positive pressure wafer transfer chamber 40 is a gate valve 28 for opening and closing the loading opening 27. Further, installed at a side wall of the housing 31 of the unloading chamber adjoining the positive pressure wafer transfer chamber 40 is an unloading opening 37 provided in order to connect the positive pressure wafer transfer chamber 40 to the unloading chamber 30, and installed at a side of the unloading opening 37 toward the positive pressure wafer transfer chamber 40 is a gate valve 38 for opening and closing the unloading opening 37.

As shown in FIGS. 1 and 2, provided at a front side wall of the housing 41 of the positive pressure wafer transfer chamber 40 is a wafer loading/unloading opening 49 for loading and unloading the wafers W into and from the positive pressure wafer transfer chamber 40, and a pod opener 50 is provided at the wafer loading/unloading opening 49. The pod opener 50 has a loading stage 51 for loading a pod P and a cap removing/restoring device 52 for removing or restoring a cap of the pod P loaded on the loading stage 51, wherein a wafer transfer opening of the pod P is opened or closed by removing or restoring the cap of the pod P loaded on the loading stage 51 by the cap removing/restoring device 52. The pod P is provided to or evacuated from the loading stage 51 of the pod opener 50 by a pod transport system (not shown) such as a rail-guided vehicle (RGV).

As shown in FIG. 1, adjacently connected to three rear side walls of the housing 12 of the negative pressure wafer transfer chamber 11 are a first CVD unit 61 serving as a first processing section, a second CVD unit 62 serving as a second processing section and a third CVD unit 63 serving as a third processing section, respectively. The number of product wafers which can be processed at a time in each of the batch processing CVD units 61-63 is 25, which is identical to that of the product wafers which can be contained in one pod P at a time. Since the first CVD unit 61, the second CVD unit 62 and the third CVD unit 63 basically have identical structures, a configuration of the above-mentioned CVD units will be described with reference to the first CVD unit 61.

As shown in FIGS. 1 to 3, the first CVD unit 61 has an antechamber 64 where the boat 79 waits. A housing 65 of the antechamber 64 has a pentagonal prism shape with two closed top and bottom ends and is of a loadlock chamber structure capable of enduring negative pressure. The antechamber 64 is large enough to accommodate the boat 79 therein. Installed at a front wall of the housing 65 of the antechamber 64 and its adjoining rear wall of the housing 12 of the negative pressure wafer transfer chamber 11 are wafer loading/unloading openings 66 and 67, respectively, which are opened or closed by a gate valve 68. Installed at a rear wall of the housing 65 of the antechamber 64 is a maintenance opening 69 to be used in loading and unloading the boat 79 to and from the antechamber 64 therethrough for maintenance. The maintenance opening 69 is normally closed by a gate valve 70.

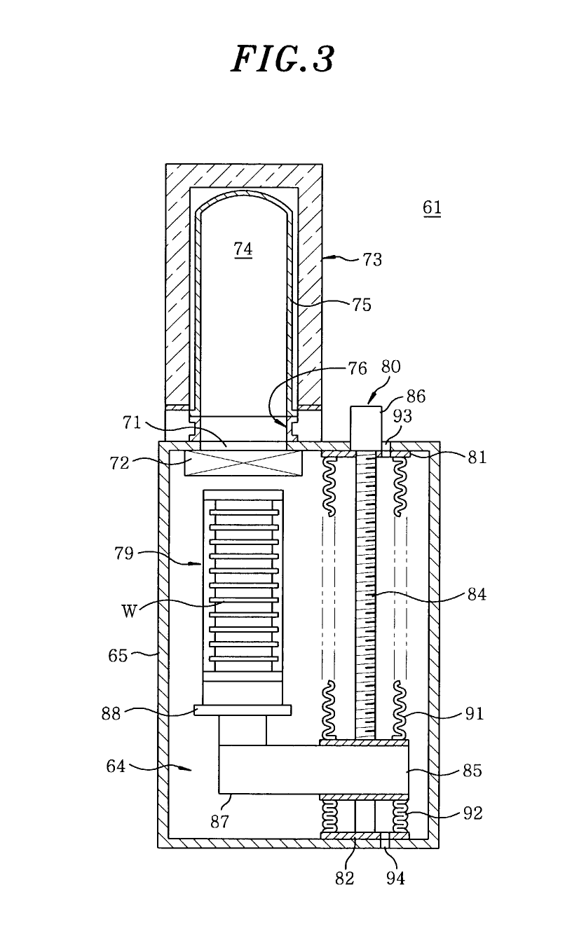

As shown in FIGS. 2 and 3, installed at the top wall of the housing 65 of the antechamber 64 is a boat loading/unloading opening 71, which is configured to be opened or closed by a shutter 72. Vertically installed above the housing 65 of the antechamber 64 is a heater unit 73, and provided inside the heater unit 73 is a process tube 75 for forming a process room 74. The process tube 75 is of a cylindrical shape having a closed upper end and an open lower end, and is concentrically disposed in the heater unit 73, wherein a cylindrical hollow portion of the process tube 75 serves as the process room 74. The process tube 75 is supported via a manifold 76 disposed on the top wall of the housing 65 of the antechamber 64, and connected to the manifold 76 are a gas supply line 77 for introducing a source gas or a purge gas into the process room 74 formed by the cylindrical hollow portion of the process tube 75 and an exhaust line 78 for evacuating the inside of the process tube 75. The manifold 76 is concentrically arranged on the boat loading/unloading opening 71 disposed at the housing 65 of the antechamber 64.

As shown in FIG. 1, installed at a rear-left corner portion of the antechamber 64 is a boat elevator 80 for raising or lowering the boat 79. As shown in FIGS. 1 and 3, the boat elevator 80 has a guide rail 83 and a feed screw shaft 84, which are vertically installed by an upper installing plate 81 and a lower installing plate 82. An elevating stage 85 is fittedly engaged with the guide rail 83, so that the elevating stage 85 can vertically move up and down along the guide rail 83. The elevating stage 85 is screw-coupled to the feed screw shaft 84 so as to vertically advance and retreat with respect thereto. Further, it is preferable to use a ball screw mechanism for the connection between the feed screw shaft 84 and the elevating stage 85 in order to confer smooth operation on the boat elevator 80 without incurring backlash. An upper portion of the feed screw shaft 84 is protruded outside the antechamber 84 by passing through the top wall of the upper installing plate 81 and the housing 65 of the antechamber 64, and is connected to a motor 86 installed outside the antechamber 64 which enables the feed screw shaft 84 to rotate in forward and reverse directions.

A horizontally protruded arm 87 is installed on a side surface of the elevating stage 85, and a sealing cap 88 is horizontally installed at an end portion of the arm 87. The sealing cap 88 functions to airtightly seal the boat loading/unloading opening 71 disposed at the housing 65 of the antechamber 64 serving as a furnace mouth of the process tube 75 and also vertically supports the boat 79. The boat 79 is configured to be loaded into or unloaded from the process room 74 of the process tube 75 in unison with the ascent and descent movement of the sealing cap 88 rendered by the ascending and the descending motion of the boat elevator 80 while horizontally holding a plural number, e.g., from 25 to 50, of the wafers W.

As shown in FIG. 3, in accordance with the first embodiment, a first bellows 91 serving as a first hollow extension/retraction body and a second bellows 92 serving as a second hollow extension/retraction body, respectively, are installed at top and bottom portions of the elevating stage 85, i.e., an outside portion of the guide rail 83 and the feed screw shaft 84, wherein hollow portions of the first bellows 91 and the second bellows 92 are airtightly separated from the antechamber 64. A first through hole 93 is provided at a position, corresponding to the hollow portion of the first bellows 91, in the top wall of the housing 65 of the antechamber 64 and the upper installing plate 81; and a second through hole 94 is provided at a position, corresponding to the hollow portion of the second bellows 92, in the bottom wall of the housing 65 of the antechamber 65 and the lower installing plate 82. Therefore, the hollow portions of the first bellows 91 and the second bellows 92 can be in communication with the atmosphere.

Hereinafter, film forming processes in the course of an IC manufacturing method will now be described with reference to the foregoing CVD apparatus in the first preferred embodiment of the invention.

25 sheets of wafers W loaded in the pod P are transferred by the pod transport system, to the CVD apparatus for performing the film forming process thereon. As shown in FIGS. 1 and 2, the transferred pod P is mounted on the loading stage 51 of the pod opener 50 after being transferred by the pod transport system. Then, the cap of the pod P is separated by the cap removing/restoring device 52 to open the wafer transfer opening of the pod P.

If the pod p is opened by the pod opener 50, the wafers W are sequentially picked up one at a time from the pod P are transferred to the temporary storage 25 of the loading chamber 20 though the loading opening 27 by the wafer transfer device 42 installed in the positive pressure wafer transfer chamber 40 of the loading chamber 20. During the transfer operation, the loading openings 22 and 23 are closed by the gate valve 24 and the negative pressure wafer transfer chamber 11 is maintained at negative pressure. If the 25 sheets of wafers are completely loaded and transferred to the temporary storage 25, the loading opening 27 provided toward the negative pressure wafer transfer chamber 40 is closed by the gate valve 28 and then the loading chamber 20 is evacuated to negative pressure by an evacuating device (not shown).

If the loading chamber 20 is depressurizeded to a predetermined pressure level, the loading openings 22 and 23 disposed at the negative pressure wafer transfer chamber 11 are opened by the gate valve 24 and, further, the wafer loading/unloading openings 66 and 67 provided at the antechamber 64 of the first CVD unit 61 are opened by the gate valve 68. Subsequently, the wafers W are sequentially picked up one at a time from the temporary storage 25 through the loading openings 22 and 23 and are charged into the boat 79 disposed in the antechamber 64 through the wafer loading/unloading openings 66 and 67 of the antechamber 64 by the wafer transfer device 10 of the negative pressure wafer transfer chamber 11. In the meantime, a facing direction of the temporary storage 25 is regulated by the rotation of the rotary actuator 26. If the 25 sheets of wafers are completely charged into the boat 79, the wafer loading/unloading openings 66 and 67 located at the antechamber 64 are closed by the gate valve 68.

In the charging operation of the 25 sheets of wafers to the boat 79, even though the elevating stroke L₁ of the wafer transfer device 10 is smaller than the wafer charging range L₂ of the boat 79 as shown in FIG. 2, the shortage length L₃ can be accommodated by the elevator 80 of the boat 79. Therefore, the 25 sheets of wafers can be completely charged to the boat 79 by the wafer transfer device 10. Thus, since the elevator 13 of the wafer transfer device 10 can be reduced in size as much as the storage length L3, a manufacturing or operating cost for the wafer transfer device 10 and the negative pressure wafer transfer chamber 11, and further the whole CVD apparatus, can be reduced.

During the charging operation of the wafers from the temporary storage 25 to the boat 79 by the wafer transfer device 10, the boat loading/unloading opening 71 is closed by the shutter 72. Therefore, the high temperature atmosphere of the process tube 75 is prevented from being flowed into the antechamber 64. Accordingly, the wafers W which have been already charged or in the process of being charged are not exposed to the high temperature atmosphere, so that such adverse effects as natural oxidation of the wafers which can be caused by the exposure to the high temperature ambience can be prevented.

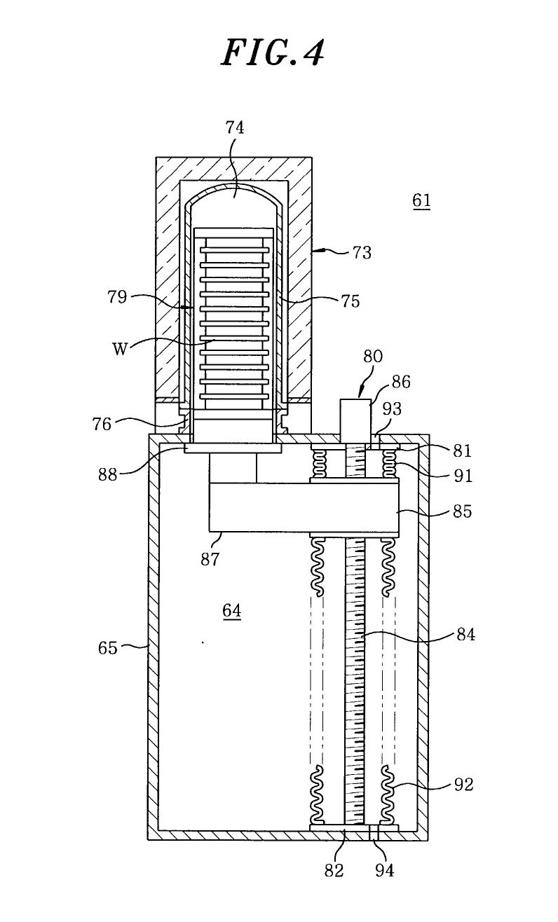

As shown in FIGS. 2 and 3, if the predetermined numbers of wafers W are charged to the boat 79, the boat loading/unloading opening 71 is opened by the shutter 72 as shown in FIG. 4. Thereafter, the boat 79 supported by the sealing cap 88 is raised by the elevating stage 85 of the boat elevator 80, thereby being loaded into the process room 74 of the process tube 75. When the boat 79 reaches its uppermost position, the boat loading/unloading opening 71 is closed by being sealed by the periphery of the top surface of the sealing cap 88 supporting the boat 79, so that the process room 74 disposed in the process tube 75 becomes in a hermetically closed state. Since the antechamber 64 is evacuated to be in a vacuum condition and therefore oxygen and moisture are removed therefrom before starting the loading process of the boat 79 into the process room 74, oxygen and moisture are prevented from being introduced into the process room 74 by loading the boat 79 into the process room 74.

Here, in the case where the elevating stage 85 is raised to load the boat 79 into the process room 74, the first bellows 91 should be retracted in an upper direction and, further, the second bellows 92 should be extended in an upper direction thereof. Since the inner space of the hollow portion of the first bellows 91 is in communication with the atmosphere through the first through hole 93, and that of the second bellows 92 is in communication with the atmosphere via the second through hole 94, the first bellows 91 and the second bellows 92 can be retracted and extended in the upper direction. Further, since the inner space of the hollow portion of the first bellows 91 and that of the second bellows 92 are separated from the antechamber 64, oxygen and moisture of the atmosphere in the hollow portions of the first and second bellows 91 and 92 and evaporated gas generated from grease coated on the feed screw shaft 84, etc are prevented from being introduced into the antechamber 64 in the course of retraction of the first bellows 91 and extension of the second bellows 92 (especially, retraction of the first bellows 91).

Thereafter, the process room 74 in the process tube 75 is evacuated via the exhaust line 78, while being airtightly isolated, in order to have a predetermined pressure by and heated to a predetermined temperature by the heater unit 73 and, thereafter, a predetermined source gas is provided therein via the gas supply line 77. As a result, a desired first film corresponding to the predetermined processing condition is formed on the wafers W.

During the film forming process performed in the first CVD unit 61, 25 sheets of wafers of a subsequent batch (hereinafter referred to as a second batch) are transferred from the pod P loaded on the loading stage 51 of the pod opener 50 to the temporary storage 25 of the loading chamber 20 by the aforementioned wafer transfer operation preformed by the wafer transfer device 42, so that 25 sheets of second batch wafers W are prepared in the loading chamber 20 in advance. During the preparing operation, since the loading openings 22 and 23 formed at the negative pressure wafer transfer chamber 11 are closed by the gate valve 24, the negative pressure wafer transfer chamber 11 is maintained at the negative pressure.

In the first CVD unit 61, if a predetermined processing time for forming the film is passed, the boat 79 is lowered by the elevating stage 85 of the boat elevator 80 as shown in FIGS. 2 and 3, so that the boat 79 having the film formed wafers W is unloaded to the antechamber 64 of the first CVD unit 61. After the boat 79 is unloaded to the antechamber 64, the boat loading/unloading opening 71 is closed by the shutter 72. Then, a loadlock of the antechamber 64 is released and, simultaneously, a nitrogen gas is supplied into the antechamber 64 via an inert gas or a neutral gas, e.g., N₂ gas supply path (not shown). The processed wafers W in the boat 79 conveyed to the antechamber 64 of the first CVD unit 61 are then cooled down by the supply of nitrogen gas to a temperature (about 200° C.) at which the wafer transfer operation can be performed by the wafer transfer device 10. If the wafers W are cooled down to the predetermined temperature, the antechamber 64 is depressurized to the predetermined negative pressure again.

After the antechamber 64 of the first CVD unit 61 is depressurized to the predetermined negative pressure, the wafer loading/unloading openings 66 and 67 of the antechamber 64 of the first CVD unit 61 are opened by the gate valve 68 and, at the same time, the wafer loading/unloading openings 66 and 67 at the antechamber 64 of the second CVD unit 62 are opened by the gate valve 68. Subsequently, the film formed wafers W are sequentially picked up one at a time from the boat 79 located in the antechamber 64 of the first CVD unit 61 by the wafer transfer device 10 of the negative pressure wafer transfer chamber 11 and are then loaded into the boat 79 of the antechamber 64 of the second CVD unit 62 through the wafer loading/unloading openings 66 and 67. After the 25 sheets of wafers are completely transferred from the first CVD unit 61 to the boat 79 of the second CVD unit 62, the wafer loading/unloading openings 66 and 67 at the antechamber 64 of the second CVD unit 62 are closed by the gate valve 68.

As described, since the transferring operation of the 25 sheets of wafers W, on each of which the first film is formed, from the first CVD unit 61 to the second CVD unit 62 is performed in the first CVD unit 61, the second CVD unit 62 and the negative pressure wafer transfer chamber 11 all of which are maintained at the negative pressure, the formation of the natural oxide film and/or the adhesion of impurities on the first film surface of each wafer W can be prevented during the wafer transferring operation.

After the wafer loading/unloading openings 66 and 67 disposed at the second CVD unit 62 are closed by the gate valve 68 after charging the 25 sheets of wafers W to the boat 79 in the second CVD unit 62, a second film is formed on the first film of the wafers W in the process room 74 of the process tube 75 disposed in the second CVD unit 62 in the same manner as in the aforementioned first CVD unit 61.

During the second film forming process in the second CVD unit 62, the 25 sheets of wafers of the second batch previously prepared at the temporary storage 25 in the loading chamber 20 are charged to the empty boat 79 of the antechamber 64 of the first CVD unit 61 by the transfer operation of the wafer transfer device 10 disposed in the aforementioned negative pressure wafer transfer chamber 11. During the transfer operation, the loading opening 27 of the loading chamber 20 disposed toward the negative pressure wafer transfer chamber 11 is closed by the gate valve 28, so that the loading chamber 20 and the negative pressure wafer transfer chamber 11 are maintained at the negative pressure.

After the 25 sheets of wafers of the second batch are completely charged to the boat 79 in the first CVD unit 61, the wafer loading/unloading openings 66 and 67 of the first CVD unit 61 are closed by the gate valve 68 and, then, the first film is formed on the wafers W of the second batch in the process room 74 of the process tube 75 disposed in the first CVD unit 61 by the aforementioned film forming process. Further, during the first film forming operation on the second batch wafers, 25 sheets of wafers W of a third batch are prepared on the temporary storage 25 of the loading chamber 20 by the preparing operation mentioned above.

Similarly as in the aforementioned first CVD unit 61, if the predetermined processing time for the second film formation is passed in the second CVD unit 62, the boat 79 is lowered by the elevating stage 85 of the boat elevator 80, so that the boat 79 having the wafers W on which the second films are formed is unloaded to the antechamber 64 of the second CVD unit 62. Thereafter, the wafers W are cooled down by the supply of nitrogen gas to a temperature (about 200° C.), at which the wafer transfer operation can be performed by the wafer transfer device 10. If the temperature of the second film formed wafers W is reduced down to a predetermined level, the antechamber 64 of the second CVD unit 62 is depressurized to the predetermined negative pressure again.

If the pressure inside the antechamber 64 of the second CVD unit 62 is lowered to the predetermined negative pressure level, the wafer loading/unloading openings 66 and 67 disposed at the antechamber 64 of the second CVD unit 62 are opened by the gate valve 68 and, at the same time, the wafer loading/unloading openings 66 and 67 disposed at the antechamber 64 of the third CVD unit 63 are opened by the gate valve 68. Then, the second film formed wafers W are sequentially picked up one by one from the boat 79 of the second CVD unit 62 by the wafer transfer device 10 of the negative pressure wafer transfer chamber 11 and are loaded to the boat 79 in the antechamber 64 of the third CVD unit 63 through the wafer loading/unloading openings 66 and 67 disposed at the antechamber 64 of the third CVD unit 63. If the 25 sheets of wafers each having the second film formed thereon are completely transferred from the second CVD unit 62 to the third CVD unit 63, the wafer loading/unloading openings 66 and 67 disposed at the antechamber 64 of the third CVD unit 63 are closed by the gate valve 68.

As described above, since the wafer transferring operation of the 25 sheets of wafers W each having the second film formed thereon from the second CVD unit 62 to the third CVD unit 63 is performed in the second CVD unit 62, the negative pressure wafer transfer chamber 11, and the third CVD unit 63 all of which are maintained at the negative pressure, the formation of the natural oxide film and/or the adhesion of impurities can also be prevented during the wafer transferring operation from the second CVD unit 62 to the third CVD unit 63.

After the wafer loading/unloading openings 66 and 67 disposed at the third CVD unit 63 are closed by the gate valve 68 after charging the 25 sheets of wafers W to the boat 79 in the third CVD unit 63, a third film is formed on the second film of each wafer W in the process room 74 of the process tube 75 disposed in the third CVD unit 63 in the same manner as in the aforementioned first CVD unit 61 and second CVD unit 62.

Further, the transferring operation of the aforementioned first film formed wafers W of the second batch can be preformed while the third film forming operation in the third CVD unit 63.

If the predetermined processing time for the third film formation is passed in the third CVD unit 63, the boat 79 is lowered by the elevating stage 85 of the boat elevator 80 in the same manner as in the aforementioned first CVD unit 61 and second CVD unit 62, so that the boat 79 having the wafers W on which the third films are formed is unloaded to the antechamber 64 of the third CVD unit 63. Thereafter, the wafers W are cooled down by the supply of nitrogen gas to a temperature (about 200° C.), at which the wafer transfer operation of the wafers W can be performed by the wafer transfer device 10. If the temperature of the third film formed wafers W is lowered down to a predetermined level, the antechamber 64 of the third CVD unit 63 is decompressed to the predetermined negative pressure again.

If the pressure inside the antechamber 64 of the third CVD unit 63 is lowered to the predetermined negative pressure, the wafer loading/unloading openings 66 and 67 disposed at the antechamber 64 of the third CVD unit 63 are opened by the gate valve 68 and, at the same time, the unloading openings 32 and 33 disposed at the unloading chamber 30 are opened by the gate valve 34. Thereafter, the third film formed wafers W are sequentially picked up one at a time from the boat 79 of the third CVD unit 63 by the wafer transfer device 10 of the negative pressure wafer transfer chamber 11 and, then, loaded to the temporary storage 35 in the unloading chamber 30 through the unloading openings 32 and 33 disposed at the unloading chamber 30. If the 25 sheets of wafers having the third films formed thereon are completely transferred from the third CVD unit 63 to the temporary storage 35, the unloading openings 32 and 33 disposed at the unloading chamber 30 are closed by the gate valve 34, and a loadlock of the unloading chamber 30 is released.

After the loadlock of the unloading chamber 30 is released, the unloading opening 37 of the unloading chamber 30 is opened by gate valve 38 and, further, the cap of the empty pod P loaded on the loading stage 51 is opened by the pod opener 50. Thereafter, the wafers W are sequentially picked up one by one from the temporary storage 35 by the wafer transfer device 42 of the positive pressure wafer transfer chamber 40 and are then charged to the pod P through the wafer loading/unloading opening 49 formed in positive pressure wafer transfer chamber 40. For the wafer unloading process, the facing direction of the temporary storage 35 is adjusted by a turn table (not shown). If all the 25 sheets of wafers W, on which the film formation is completed, are accommodated in the pod P, the cap of the pod P is restored to the wafer transfer opening of the pod P by the cap removing/restoring device 52 to thereby close the pod P.

The closed pod P is then transferred from the loading stage 51 for a subsequent process by the pod transport system.

By repeating the aforementioned film forming operations, the 25 sheets of wafers contained in one pod P are batch-processed for the formation of the first, the second and the third film sequentially.

Following effects can be achieved by the preferred embodiment of the present invention.

1) By arranging the CVD units each having the antechamber of the loadlock chamber structure, around the negative pressure wafer transfer chamber having the wafer transferr device, the transferring operation of the film formed wafers between the CVD units can be performed under the negative pressure, so that the formation of the natural oxide film and/or the adhesion of the impurities on the surface of a wafer and the surface of a film can be prevented.

2) By setting up the number of product wafers which can be processed simultaneously in each CVD unit being not greater than 25, which is the maximum number of wafers which can be carried by one pod for use in carrying product wafers and configuring the substrate processing apparatus such that each CVD unit can simultaneously process the whole product wafers carried by one pod, the formation of the first, the second and the third film can be sequentially batch-processed on a pod basis, so that the throughput of the CVD apparatus can be increased significantly compared with a single wafer process.

3) By arranging the loading chamber and the unloading chamber having the loadlock chamber structure, around the negative pressure wafer transfer chamber having the wafer transfer device, the loading operation of the wafers to be processed and the unloading operation of the processed wafers can be carried out while the film forming process are performed in the CVD units, so that the throughput of the CVD apparatus can be further increased.

4) By enabling the nitrogen to be supplied to the antechamber of the each of CVD unit, the processed wafers can be forcedly cooled down, so that the throughput of the CVD apparatus can be still further increased.

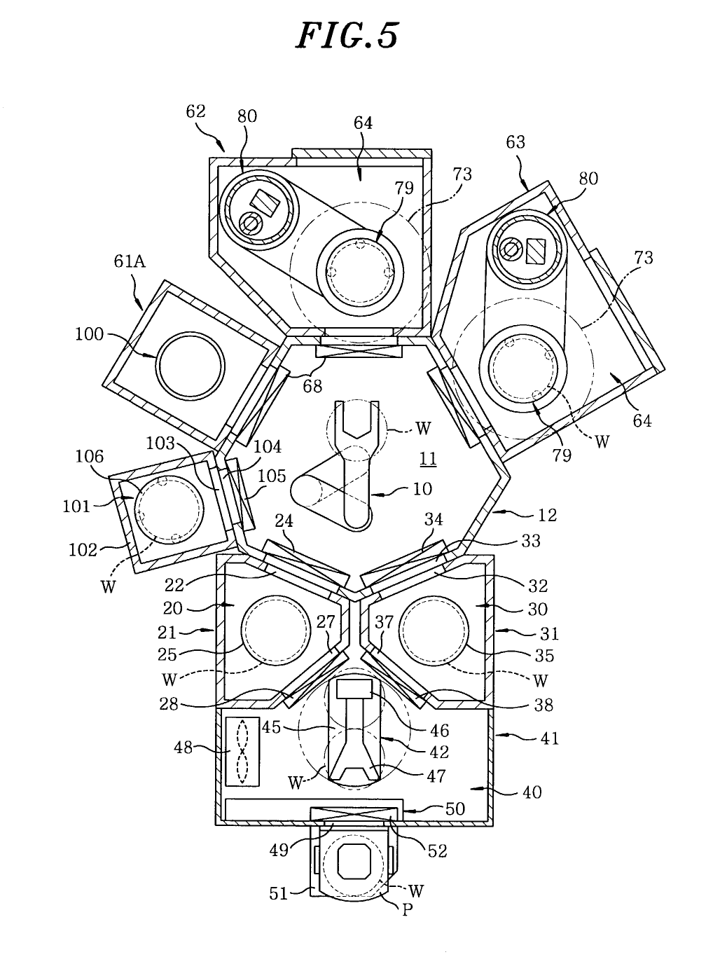

Referring to FIG. 5, there is illustrated a horizontal cross-sectional view of a multichamber CVD apparatus in accordance with a second preferred embodiment in the present invention.

The batch-type CVD apparatus in accordance with the second preferred embodiment of the present invention is different from that of the first preferred embodiment, in that a single wafer CVD reactor 100 is installed in a first CVD unit 61A and a buffer chamber 101 is further arranged at one side wall of a housing 12 of a negative pressure wafer transfer chamber 11. A housing 102 of the buffer chamber 101 has a hexahedral shape with two closed top and bottom ends and is of a loadlock chamber structure capable of maintaining the negative pressure.

Installed at two adjoining side walls of the housing 102 of the buffer chamber 101 and the housing 12 of the negative pressure wafer transfer chamber 11 are wafer loading/unloading openings 103 and 104. A gate valve 105 is installed at the wafer loading/unlading opening 104 toward the negative pressure wafer transfer chamber 11. A temporary storage 106 having an identical structure to that of the boat 79 is installed in the buffer chamber 101. Further, the gate valve 105 can be omitted if required.

In the CVD apparatus in accordance with the second embodiment, since the single wafer CVD reactor 100 is installed in the first CVD unit 61A, a first film forming process is carried out on one sheet of wafer at a time and upon completing the first film forming process on a wafer, the processed wafer is transferred to the temporary storage 106 of the buffer chamber 101 by the wafer transfer device 10 of the negative pressure wafer transfer chamber 11. Further, if one batch of processed wafers W 25 sheets of wafers corresponding to one pod is accumulated in the temporary storage 106, those wafers are moved from the buffer chamber 101 to the second CVD unit 62 by the wafer transfer device 10 of the negative pressure wafer transfer chamber 11.

As for the wafers of the first batch, it may be possible to transfer each wafer directly from the first CVD unit 61A to the second CVD unit 62 without passing through the temporary storage 106 of the buffer chamber 101. However, in subsequent batch, since the film forming process in the first CVD unit 61A is performed during the second film forming process in the second CVD unit 62. Therefore, it is impossible to directly transfer the wafers W from the first CVD unit 61A to the second CVD unit 62. As a result, there may occur a waiting time period. In accordance with the present invention, however, the waiting time can be considerably reduced or removed by loading and transferring the first film formed wafers W from the first CVD unit 61A to the temporary storage 106 of the buffer chamber 101 to thereby temporarily store the wafers W.

In accordance with the second embodiment, the batch process can be performed on a pod basis even with the single wafer CVD reactor employed. Therefore, the waiting time due to the single wafer process can be minimized, and, therefore, the single wafer process can be employed together with the batch process without lowering the throughput of the CVD apparatus.

The present invention is not intended to be limited by the specific embodiments described above, but should be construed that the preferred embodiments described above can be modified without departing from the scope of the invention.

For example, the number of the CVD units arranged around the negative pressure wafer transfer chamber is not limited to three. It can be any number greater 1.

The processing units arranged around the negative pressure wafer transfer chamber can be any other units than the batch-type CVD apparatus and the single wafer CVD reactor. The processing units may include a CVD apparatus processing two wafers at a time, a plasma CVD apparatus, or a wafer processing unit having a substrate processing apparatus such as an oxidation apparatus, a diffusion apparatus, a sputtering apparatus, or a dry etching apparatus.

Dummy wafers may be accommodated in a boat permanently, or they can be exchanged periodically or non-periodically. Further, the dummy wafers can be stored in a stocker provided in the negative pressure or the positive pressure wafer transfer chamber and can be charged to the boat when necessary.

Even though the aforementioned preferred embodiments describe the CVD film forming processes, the present invention can be equally applied to a substrate processing apparatus which can be used in an oxidation treatment, a diffusion process, an annealing process, a plasma treatment, a sputtering process, a dry etching process and the combination thereof.

Examplary sequential processes are listed in Table. It is preferable that a preprocessing in Table is carried out on a single wafer basis.

TABLE

| | | | Fourth |
|---|---|---|---|
| First processing | Second processing | Third process- | processing |
| section | section | ing section | section |
| Preprocessing | Forming | | |
| (removing natural | poly-silicon film | | |
| oxide film) | | | |
| Preprocessing | Forming | | |
| (removing natural | epitaxial | | |
| oxide film) | silicon film | | |
| Preprocessing | Forming | | |
| (removing natural | epitaxial | | |
| oxide film) | silicon-germanium | | |
| | film | | |
| Preprocessing | Forming Hi-k | Forming | |
| (removing natural | (high dielectric) | poly-silicon | |
| oxide film) | gate oxide film | film | |
| Preprocessing | Forming Hi-k | Forming poly- | |
| (removing natural | (high dielectric) | silicon- | |
| oxide film) | gate oxide film | germanium | |
| | | film | |
| Preprocessing | Forming a HSG-Si | Forming | Forming |
| (removing natural | film | silicon nitride | poly-silicon |
| oxide film) | | film | film |
| Previous process | Oxidation process | Forming a | Forming |
| (removing a natural | | silicon nitride | poly- |
| oxide film) | | film | silicon- |
| | | | germanium |
| | | | film |

Further, the present invention can also be applied to various substrate processes for manufacturing a liquid crystal panel, a magnetic disk or an optical disk as well.

While the invention has been shown and described with respect to the preferred embodiments, it will be understood by those skilled in the art that various changes and modifications may be made without departing from the spirit and scope of the invention as defined in the following claims.

What is claimed is:

1. A substrate processing apparatus comprising:
at least two processing units provided around a substrate transfer chamber which includes a substrate transfer device for transferring substrates;
wherein said at least two processing units include at least one batch processing unit, M number of product substrates being processed simultaneously in one batch process, with M being set to be less than or equal to the maximum number of product substrates to be contained in a product substrate carrier, and all the product substrates contained in the product substrate carrier being processed in one batch process carried out in said at least one batch processing unit.

2. The substrate processing apparatus of claim 1, wherein said at least two processing units further include a single substrate processing unit provided around the substrate transfer chamber for processing one or P number of product substrates at a time, P being smaller than M; and
the substrate processing apparatus further comprising a stocker provided around the substrate transfer chamber for temporarily storing said one or P number of the substrates.

3. A substrate processing apparatus comprising:
at least one batch processing unit, provided around a substrate transfer chamber including a substrate transfer device for transferring substrates, for processing N number of product substrates simultaneously in one batch process;
a single substrate processing unit provided around the substrate transfer chamber for processing one or P number of product substrates at a time, P being smaller than N; and
a stocker provided around the substrate transfer chamber for temporarily storing said one or P number of product substrates processed by the single substrate processing unit.

4. A method for fabricating a semiconductor device, comprising the steps of:
processing one or more product substrates in a first processing unit arranged around a substrate transfer chamber,
transferring the product substrates from the first processing unit to a second processing unit arranged around the substrate transfer chamber;
processing the product substrates in the second processing unit,
wherein said two processing units include at least one batch processing unit, M number of product substrates being processed simultaneously in one batch process by said at least one batch processing unit with M being set to be less than or equal to the maximum number of product substrates to be contained in a product substrate carrier, and all the product substrates contained in the product substrate carrier being processed in one batch process carried out in said at least one batch processing unit.

5. The method of claim 3, wherein at least one loading chamber is provided around the substrate transfer chamber for loading substrates into the substrate transfer chamber, and
the method further comprising the step of providing subsequent substrates to be processed in said at least one loading chamber while substrates are processed in the first processing unit.

6. The method of claim 3, wherein a single substrate processing unit is provided around the substrate transfer chamber for processing one or P number of substrates at a time, P being smaller than M, and a stocker is arranged around the substrate transfer chamber for temporarily storing said one or P number of substrates, and
the method further comprising the steps of:
processing said one or P number of substrates in the single substrate processing unit; and
transferring said one or P number of substrates processed by the single substrate processing unit to the stocker.

7. The method of claim 5, further comprising the steps of:
repeating the steps of processing and transferring said one or P number of substrates, and processing all the product substrates contained in the substrate carrier in the single substrate processing unit; and
transferring the substrates processed by the single substrate processing unit from the stocker to one of said at least one batch processing unit.

8. A method for fabricating a semiconductor device, comprising the steps of:
processing at least one substrate in one processing unit;
introducing an inert or a neutral gas into the processing unit after the processing step, to increase a pressure level therein to be higher than that during a process of transferring substrates;
lowering the pressure level of said processing unit down to the pressure level during the process of transferring substrates; and
transferring the substrates processed in said processing unit.
